(19) United States
(12) Patent Application Publication
(10) Pub. No.: US 2008/0158206 A1
(43) Pub. Date: Jul. 3, 2008

(54) SIGNAL TRANSFER APPARATUS

(76) Inventors: Tomoya Ishikawa, Osaka (JP); Yuuki Fuchigami, Osaka (JP)

Correspondence Address: MCDERMOTT WILL & EMERY LLP, 600 13TH STREET, NW, WASHINGTON, DC, 20005-3096, US

(21) Appl. No.: 11/952,576

(22) Filed: Dec. 7, 2007

(30) Foreign Application Priority Data
Dec. 8, 2006 (JP) 2006-331646

(51) Int. Cl. G05B 1/02; G06F 3/038; G09G 5/00; H03K 5/22

(52) U.S. Cl. 345/204; 327/65

(57) ABSTRACT

A signal transfer apparatus comprises a differential signal generating part which receives an input signal from a positive-electrode side input terminal and an input signal from a negative-electrode side input terminal, and outputs a differential signal obtained from the input signals from both the input terminals; a first selecting part which receives a selection signal from a selection signal input terminal, the input signal from the positive-electrode side input terminal, and the input signal from the negative-electrode side input terminal, and selects and outputs either the input signal from the negative-electrode side input terminal or the input signal from the positive-electrode side input terminal in accordance with a logic of the selection signal and a logic of either the input signal from the positive-electrode side input terminal or the input signal from the negative-electrode side input terminal; and a second selecting part which selects and outputs either an output of the differential signal generating part or an output of the first selecting part in accordance the logic of the selection signal from the selection signal input terminal.

### FIELD OF THE INVENTION

The present invention relates to a signal transfer apparatus that is capable of switching between a differential signal receiving mode and a single-end signal receiving mode. The signal transfer apparatus according to the present invention is used effectively in the filed of display apparatuses in particular.

### BACKGROUND OF THE INVENTION

In a display apparatus such as a flat panel display, display drivers are arranged in parallel for applying voltage signals to display elements in accordance with display data. Display data, a reference clock, a control signal, and the like are supplied to each of the display drivers. The signal transfer apparatus of the present invention is mainly directed to such display drivers.

Recently, size and usage of flat panel displays have been diversified. In accordance with this, types of signals supplied to the display drivers have been diversified as well. For example, single-end signal interface, RSDS (Reduced Swing Differential Signaling; registered trademark), LVDS (Low Voltage Differential Signaling; registered trademark) are supplied to the display drivers. The latter two are differential signals. With such backgrounds, it is desired to develop a display driver that can deal with various types of supplied signals (see Japanese Unexamined Patent Publication 2005-284217 (pp. 6-11, FIG. 1-FIG. 11), for example).

As a part of technical developments for dealing with such various interfaces described above, a display driver is required to be able to deal with inputs of both differential signals and single-end signals; deal with both positive logic signals and negative logic signals when receiving the input of the single-end signals; and reduce the number of terminals as much as possible.

### SUMMARY OF THE INVENTION

An object of the present invention therefore is to provide a signal transfer apparatus which is capable of receiving both differential signals and single-end signals, capable of dealing with both positive logic signals and negative logic signals when receiving the single-end signals, while reducing the number of terminals as much as possible.

Further, in the case of the single-end interface, there is an issue of EMI (electromagnetic interference) which is generated on signal wiring. Therefore, it is also an object of the present invention to reduce EMI when receiving input of the single-end signals.

A signal transfer apparatus according to the present invention comprises: a differential signal generating part which receives an input signal from a positive-electrode side input terminal and an input signal from a negative-electrode side input terminal, and outputs a differential signal obtained from the input signals from both the input terminals;
a first selecting part which receives a selection signal from a selection signal input terminal, the input signal from the positive-electrode side input terminal, and the input signal from the negative-electrode side input terminal, and selects and outputs either the input signal from the negative-electrode side input terminal or the input signal from the positive-electrode side input terminal in accordance with a logic of the selection signal and a logic of either the input signal from the positive-electrode side input terminal or the input signal from the negative-electrode side input terminal; and
a second selecting part which selects and outputs either an output of the differential signal generating part or an output of the first selecting part in accordance with the logic of the selection signal from the selection signal input terminal.

In this structure, when a first condition signal (either “L” or “H”) is inputted as the selection signal, the second selecting part selects the output of the differential signal generating part (differential signal receiving mode). Further, when a second condition signal (either “H” or “L”) is inputted as the selection signal, the second selecting part selects the output of the first selecting part (single-end signal receiving mode). At this time, the first selecting part selects the input signal from the negative-electrode side input terminal according to a combination of the second condition signal and the logic-fixed input signal from the positive-electrode side input terminal, and selects the input signal from the positive-electrode side input terminal according to a combination of the second condition signal and the logic-fixed input signal from the negative-electrode side input terminal.

In the signal transfer apparatus of the above-described structure, the input terminal for the differential signal can be used also as the input terminal for the single-end signal. Further, it is possible for the signal transfer apparatus to have three selectable modes such as a mode for selecting the differential signal obtained based on the difference between the input signal from the positive-electrode side input terminal and the input signal from the negative-electrode side input terminal, a mode for selecting the input signal from the positive-electrode side input terminal, and a mode for selecting the input signal from the negative-electrode side input terminal.

That is, the signal transfer apparatus is capable of receiving the signal, whether it is the differential signal or the single-end signal. Further, when receiving the single-end signal, the signal transfer apparatus is capable of executing operations, whether the single-end signal is a positive logic signal or a negative logic signal, without requiring a special signal for switching between the positive logic input and the negative logic input. Accordingly, an increase in the number of terminals can be suppressed. As a result, it becomes possible to deal with various kinds of interfaces with a single signal transfer apparatus.

In the signal transfer apparatus described above, the differential signal generating part is controlled so that it is in an operational state when the selection signal is a first condition signal, and in a non-operational state when the selection signal is a second condition signal. With this structure, the differential signal generating part becomes active when the differential signal is inputted and is turned non-operational when the single-end signal is inputted. Thus, consumption of the electric current can be reduced.

In the signal transfer apparatus described above, the first selecting part is controlled so that it is in an operational state when the selection signal is a second condition signal, and in a non-operational state when the selection signal is a first condition signal. With this structure, the first selecting part becomes active when the single-end signal is inputted and is turned non-operational when the differential signal is inputted. Thus, consumption of the electric current can be reduced.

In the signal transfer apparatus described above, a delay adjusting part, which is capable of switching its delay effect in accordance with the logic of the selection signal, is inserted between the first selecting part and the second selecting part. The paths for the signals to be transferred differ between the case of the differential signal receiving mode and the case of the single-end signal receiving mode, so that a difference arises in the delay time between those cases. Therefore, the delay adjusting part is inserted between the first selecting part and the second selecting part to equate the delay time of the differential signal with that of the single-end signal. This structure makes it possible to absorb the delay time difference generated due to a difference in the path lengths between the differential signal receiving mode and the single-end signal receiving mode, so that the signal reach time can be made equal in both the modes.

In the signal transfer apparatus as described above, the first selecting part is formed to have its structural elements at the same level at both a positive electrode and a negative electrode, and a resistance value of wiring up to the positive-electrode side terminal and a resistance value of wiring up to the negative-electrode side input terminal are designed to be equal with each other. With this structure, the parasitic capacitance for the positive-electrode side input terminal and the parasitic capacitance for the negative-electrode side input terminal become equal. As a result, it becomes unnecessary to adjust timing for both the positive logic input and the negative logic input.

In the signal transfer apparatus described above, the first selecting part is constituted with a NAND circuit and a NOR circuit. Alternatively, the first selecting part is constituted only with a NOR circuit. The NAND circuit or the NOR circuit, when one of the inputs is fixed to “H” or “L”, works as an inverter and selects the other input, and then, after inverting it, outputs the resultant.

A display driver according to the present invention comprises a plurality of any of the above-described signal transfer apparatuses arranged in parallel, wherein a first signal transfer apparatus that is in a mode for inputting a positive logic clock to the positive-electrode side input terminal and for inputting a logic-fixed control signal to the negative-electrode side input terminal, and a second signal transfer apparatus that is in a mode for inputting a negative logic clock to the negative-electrode side input terminal and for inputting the logic-fixed control signal to the positive-electrode side input terminal are arranged alternately.

In a display driver having a plurality of the signal transfer apparatuses arranged in parallel along the sides of the display panel, when a clock is transferred from a controller via signal wiring, the clock may become a cause of generating EMI (electromagnetic noise) against the data signal flowing in the neighboring signal wiring. Such EMI needs to be suppressed. That is, the EMI generated from the signal wiring of the positive logic clock and the EMI generated from the signal wiring of the negative logic clock can be electromagnetically offset in the single-end signal receiving mode, by alternately arranging the first signal transfer apparatus and the second signal transfer apparatus and by providing the signal wiring for supplying the positive logic clock to the first signal transfer apparatus and the signal wiring for supplying the negative logic clock to the second signal transfer apparatus to be lined side by side. As a result, the EMI can be reduced.

A dot-matrix type display apparatus according to the present invention comprises: a data driver in which a plurality of any signal transfer apparatuses described above are arranged in parallel; and a controller for supplying clocks and control signals to the plurality of signal transfer apparatuses.

### BRIEF DESCRIPTION OF THE DRAWINGS

FIG. 1 is a circuit diagram for showing a structure of a signal transfer apparatus according to a first embodiment of the present invention;

FIG. 2 is a circuit diagram for showing a structure of a signal transfer apparatus according to a second embodiment of the present invention;

FIG. 3 is a circuit diagram for showing a structure of a signal transfer apparatus according to a third embodiment of the present invention;

FIG. 4 is a circuit diagram for showing a structure of a signal transfer apparatus according to a fifth embodiment of the present invention; and

FIG. 5 is a circuit diagram for showing a structure of a display driver (data driver) according to a sixth embodiment of the present invention.

### DETAILED DESCRIPTION OF THE INVENTION

Hereinafter, preferred embodiments of a signal transfer apparatus according to the present invention will be described in detail by referring to the accompanying drawings.

### First Embodiment

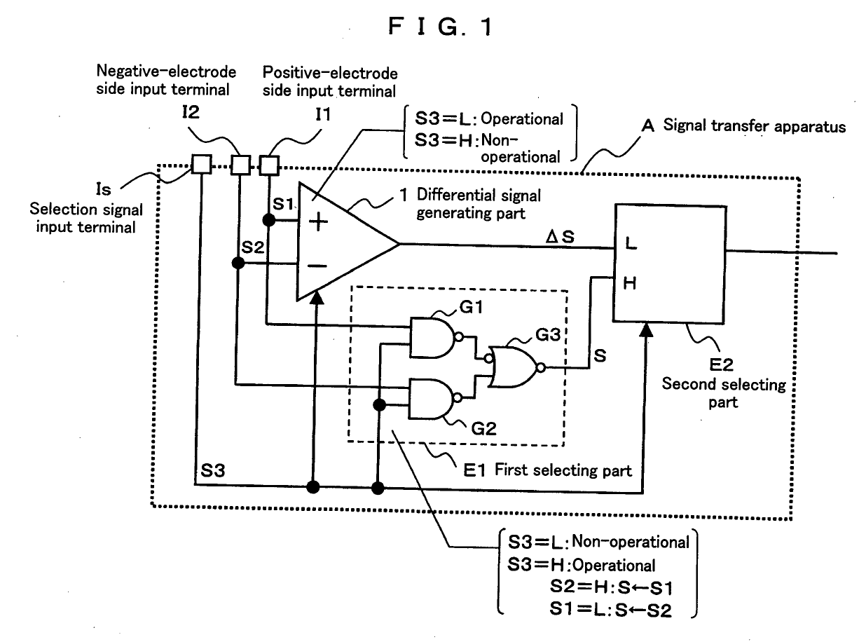

FIG. 1 is a circuit diagram for showing a structure of a signal transfer apparatus according to a first embodiment of the present invention. In FIG. 1, “A” is a signal transfer apparatus (for example, a liquid crystal driver or a data driver), “I1” is a positive-electrode side input terminal for differential signals, “I2” is a negative-electrode side input terminal for the differential signals, “Is” is a selection signal input terminal, “1” is a differential signal generating part, “E1” is a first selecting part, and “E2” is a second selecting part.

The signal transfer apparatus A can switch between two receiving modes, i.e., a differential signal receiving mode and a single-end signal receiving mode, in accordance with a logic of a selection signal S3 from the selection signal input terminal Is. That is, when the selection signal S3 is “L” level, the differential signal receiving mode is selected and, when the selection signal S3 is “H” level, the single-end signal receiving mode is selected. Details of the signal transfer apparatus A will be described hereinafter.

The differential signal generating part 1 receives an input signal S1 from the positive-electrode side input terminal I1 and an input signal S2 from the negative-electrode side input terminal I2 as the input, and makes a differential signal of both the input signals and outputs the signal. The differential signal generating part 1 operates when the selection signal S3 from the selection signal input terminal Is is “L” level, and is in a non-operational state when the selection signal S3 is “H” level.

The first selecting part E1 operates when the selection signal S3 from the selection signal input terminal Is is “H” level, selects either the input signal S1 from the positive-electrode side input terminal I1 or the input signal S2 that is from the negative-electrode side input terminal I2, and outputs the selected one to the second selecting part E2. That is, the input signal S1 is selected with the input signal S2 fixed to “H” level, while the input signal S2 is selected with the input signal S1 fixed to “L” level. When the selection signal S3 is “L” level, the first selecting part E1 is turned non-operational. In the case of the illustration, the first selecting part E1 is constituted with two NAND circuits and a single NOR circuit.

The second selecting part E2 selects and outputs a differential signal ΔS outputted from the differential signal generating part 1, when the selection signal S3 from the selection signal input terminal Is is “L” level, and selects and outputs a selection result signal S outputted from the first selecting part E1, when the selection signal E3 is “H” level.

Next, there will be described actions of the signal transfer apparatus according to this embodiment that is structured in the manner described above.

(1) Actions Under Differential Signal Receiving Mode

When the selection signal S3 is “L” level and the differential signal receiving mode is selected, the differential signal generating part 1 becomes active. The input signal S1 is inputted to the positive-electrode side input terminal I1, the input signal S2 is inputted to the negative-electrode side input terminal I2, and the differential signal ΔS generated through figuring out a difference between both the signals by the differential signal generating part 1 is outputted to the second selecting part E2. Since the selection signal E3 is “L” level, the second selecting part E2 selects and outputs the differential signal ΔS from the differential signal generating part 1.

For the first selecting part E1, both of the two NAND circuits are closed since the selection signal S3 is “L” level. The selection result signal S is fixed to “L” level. However, the selection result signal S is not selected by the second selecting part E2.

(2) Actions Under Single-End Signal Receiving Mode

When the selection signal S3 is “H” level and the single-end signal receiving mode is selected, both of the two NAND circuits in the first selecting part E1 are opened. The operating characteristic of the NAND circuit is such that when either input inputs is “H” level, it operates as an inverter for the other input.

First, described is a case where a positive logic input is inputted to the positive-electrode side input terminal. At this time, the negative-electrode side input terminal 12 is fixed to “H” level. As a result, output of a NAND circuit G2 in the first selecting part E1 maintains “L” at all times, and input of a NOR circuit G3 maintains “L” at all times. Thus, the input signal S1 from the positive-electrode side input terminal I1 becomes the selection result signal S after going through the NAND circuit G1 and the NOR circuit G3, and it is outputted to the second selecting part E2. Since the selection signal S3 is “H” level, the second selecting part E2 selects and outputs the selection result signal S from the first selecting part E1. The selection result signal S changes in accordance with the positive logic signal inputted to the positive-electrode side input terminal I1.

Next, described is a case where a negative logic input is inputted to the negative-electrode side input terminal I2. At this time, the positive-electrode side input terminal I1 is fixed to “L” level. As a result, output of a NAND circuit G1 in the first selecting part E1 maintains “H” at all times, and input of the NOR circuit G3 maintains “L” at all times. Thus, the input signal S2 from the negative-electrode side input terminal I2 becomes the selection result signal S after going through the NAND circuit G2 and the NOR circuit G3, and it is outputted to the second selecting part E2. Since the selection signal S3 is “H” level, the second selecting part E2 selects and outputs the selection result signal S from the first selecting part E1. The selection result signal S changes in accordance with the negative logic signal inputted to the negative-electrode side input terminal I2.

In the meantime, when the section signal S3 is made to be “H” level, the differential signal generating part 1 becomes non-operational, so that consumption of the electric current can be reduced.

With the present embodiment, it is possible to use the terminal I1 and the terminal I2 for the differential signal input terminal and the single-end signal input terminal in common, and to provide three selectable conditions, i.e.; a mode for selecting the differential signal ΔS that is a difference between the input signal S1 from the positive-electrode side input terminal I1 and the input signal S2 from the negative-electrode side input terminal I2, a mode for selecting the input signal S1 from the positive-electrode side input terminal I1, and a mode for selecting the input signal S2 from the negative-electrode side input terminal I2. Further, when a single-end signal is inputted, it is possible for the signal transfer apparatus to operate regardless of whether the single-end signal input is a positive logic input or a negative logic input, without using a special signal for switching between the positive-logic input and the negative logic input. This makes it possible to suppress an increase in the number of terminals as much as possible.

### Second Embodiment

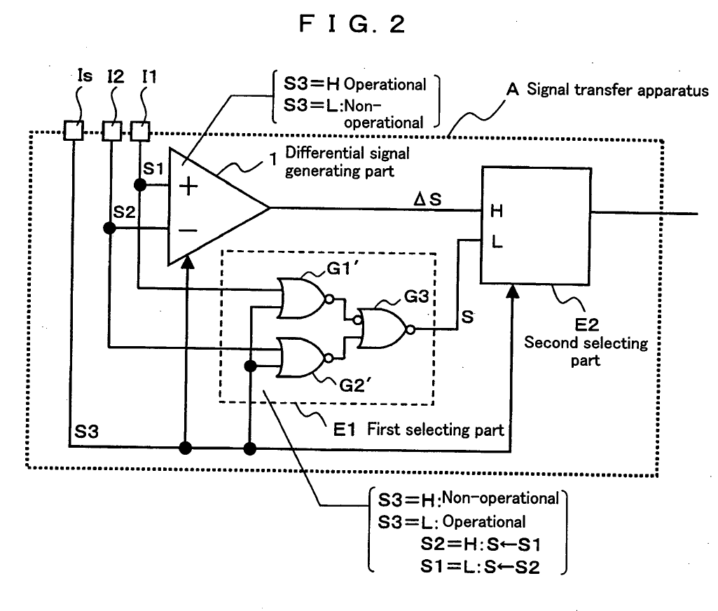

FIG. 2 is a circuit diagram for showing a structure of a signal transfer apparatus according to a second embodiment of the present invention. In FIG. 2, the same reference numerals as those of FIG. 1 according to the first embodiment indicate the same structural elements. The structure peculiar to the second embodiment is as follows. The first selecting part E1 is constituted by using NOR circuits only. “G1′” and “G2′” are the NOR circuits. The operation logic of the second selecting part E2 is reverse to the case of the first embodiment. The other structures are the same as those of the first embodiment, so that explanations thereof will be omitted.

In this embodiment, when the selection signal S3 for a receiving mode from the selection signal input terminal Is is “L” level, the single-end signal receiving mode is set. When the input signal S1 that is a positive logic input is inputted to the positive-electrode side input I1, the input signal S2 from the negative-electrode side input terminal 12 is fixed to “H” level. Thereby, the input signal S1 as the single-end signal inputted to the positive-electrode side input terminal I1 is selected and transferred to the second selecting part E2. Then, the input signal S1 from the positive-electrode side input terminal I1 is selected by the second selecting part E2 where the “L”-selected input terminal is asserted according to the selection signal S3 that is fixed to “L” level, and the selected input signal S1 is inputted into the inside of the circuit.

In the meantime, when the input signal S2 that is a negative logic input is inputted to the negative-electrode side input I2, the input signal S1 from the positive-electrode side input terminal I1 is fixed to “L” level. Thereby, the input signal S2 as the single-end signal inputted to the negative-electrode side input terminal I2 is selected. Thus, the input signal S2 from the negative-electrode side input terminal I2 is selected by the second selecting part E2, and inputted into the inside of the circuit.

### Third Embodiment

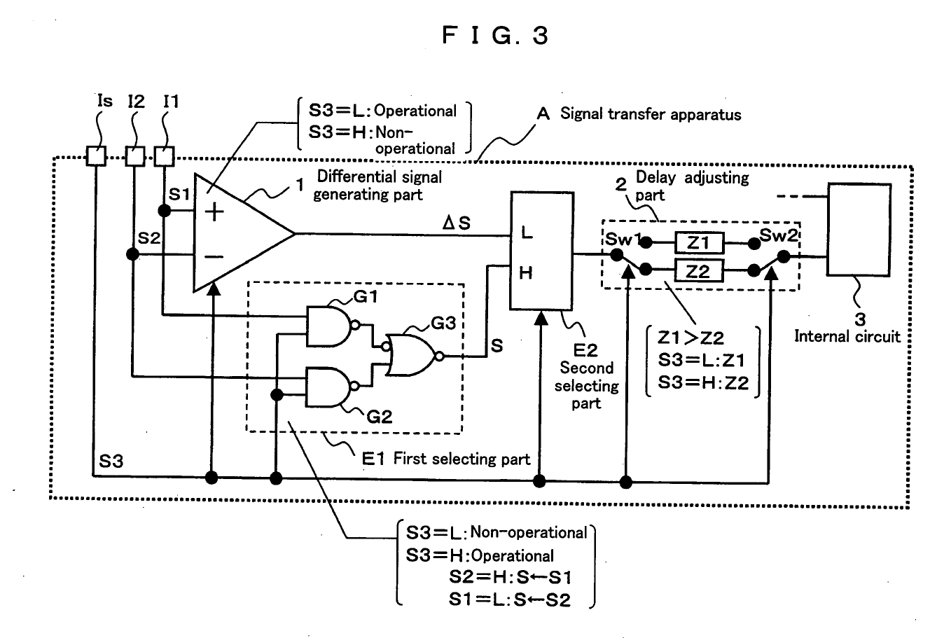

FIG. 3 is a circuit diagram for showing a structure of a signal transfer apparatus according to a third embodiment of the present invention. This embodiment is characterized by its delay adjusting function. In FIG. 3, “2” is a delay adjusting part, and “3” is an internal circuit. The other structures are the same as those of the first embodiment, so that explanations thereof will be omitted.

In a case of the differential signal receiving mode, the inputted signal travels through the differential signal generating part, and it is selected by the second selecting part E2 and transmitted to the internal circuit 3. On the other hand, in the case of the single-end signal receiving mode, the inputted signal travels through the first selecting part E1 and it is selected by the second selecting part E2 and transmitted to the internal circuit 3. At this time, the signal paths differ depending on the mode, so that there is a difference between the two modes regarding delay time. Therefore, the delay adjusting part 2 is inserted between the first selecting part E1 and the second selecting part E2 so that the time required for a signal to reach the internal circuit 3 becomes equal whether it is a differential signal or a single-end signal. The delay adjusting part 2 is constituted to switch two delay effect elements Z1 and Z2 with switching elements Sw1 and Sw2. The switching elements Sw1 and Sw2 are configured to be switched by the selection signal S3. The delay effect element Z1 has a larger delay effect than the delay effect element Z2.

In the case of the differential signal receiving mode, the selection signal S3 is set to “L” level, and the differential signal ΔS from the differential signal generating part 1 is outputted from the second selecting part E2. At this time, the selection signal S3 has been set to “L” level, so that the switching elements Sw1 and Sw2 select the delay effect element Z1. Therefore, the differential signal ΔS outputted from the second selecting part E2 is inputted to the internal circuit 3 through the delay effect element Z1. The delay effect element Z1 produces a larger delay effect.

On the other hand, under the single-end signal receiving mode, the selection signal S3 is set to “H” level, and the selection result signal S from the first selecting part E1 is outputted from the second selecting part E2. At this time, the selection signal S3 has been set to “H” level, so that the switching elements Sw1 and Sw2 select the delay effect element Z2. Therefore, the selection result signal S outputted from the second selecting part E2 is inputted to the internal circuit 3 through the delay effect element Z2. The delay effect element Z2 produces a smaller delay effect.

As described above, the delay adjusting part 2 is inserted in this embodiment. Therefore, it is possible to absorb the difference regarding the delay time generated due to the difference in the path lengths between the differential signal receiving mode and the single-end signal mode, so that the time for the signals to reach the internal circuit 3 can be made identical in either of these two modes.

### Fourth Embodiment

A fourth embodiment of the present invention employs the circuit structure of FIG. 1, FIG. 2, or FIG. 3 described above.

In this embodiment, in order for parasitic capacitance of the positive-electrode side input terminal I1 and that of the negative-electrode side input terminal I2 of the differential signal to become equal, a wiring resistance value from the positive-electrode side input terminal I1 and a wiring resistance value from the negative-electrode side input terminal I2 to the first selecting part E1 are made to be equal, and the structural elements of the first selecting part E1 itself are designed to have the same value for both the positive electrode and the negative electrode. As a result, it becomes unnecessary to adjust timing, whether an input is a positive logic input or a negative logic input.

### Fifth Embodiment

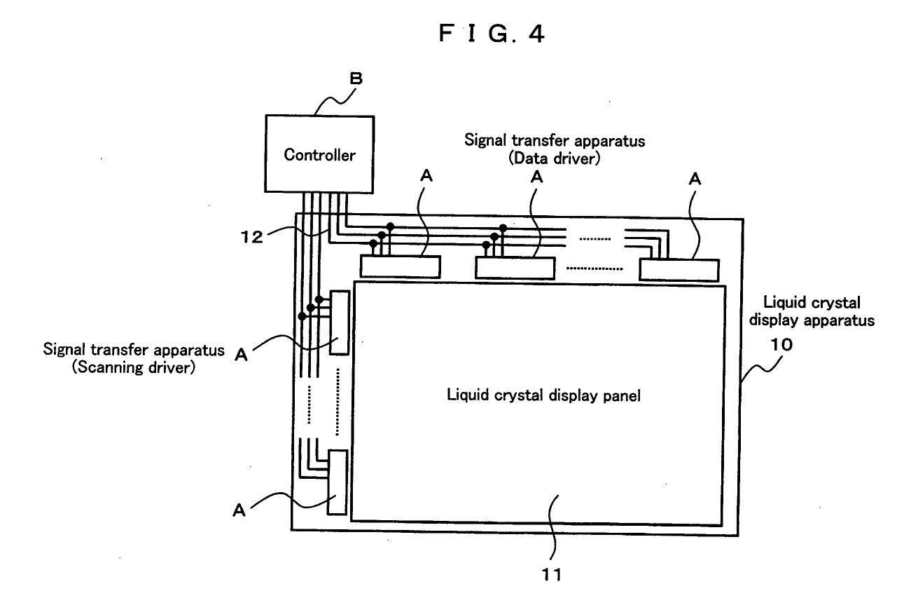

FIG. 4 is a schematic block diagram of a liquid crystal display apparatus according to a fifth embodiment of the present invention. A plurality of the above-described signal transfer apparatuses A are arranged in parallel along the upper side of a liquid crystal display panel 11, and a plurality of the signal transfer apparatuses A are arranged in parallel along the left side of the liquid crystal display panel 11. The signal transfer apparatuses A thus arranged may be any of the apparatuses A described in the first to fourth embodiments. The signal transfer apparatuses A lined in the lateral direction are constituted as data drivers which apply voltages to the liquid crystal display elements in accordance with display data, and the signal transfer apparatuses A lined in the longitudinal direction are constituted as scanning drivers for selecting active lines. Each of the signal transfer apparatuses A is connected to a controller B via signal wiring 12. The controller B transmits a display data signal, a clock signal, a control signal, and the like to the signal transfer apparatuses A. The signal transfer apparatuses A may be connected with each other by cascade-type connection.

### Sixth Embodiment

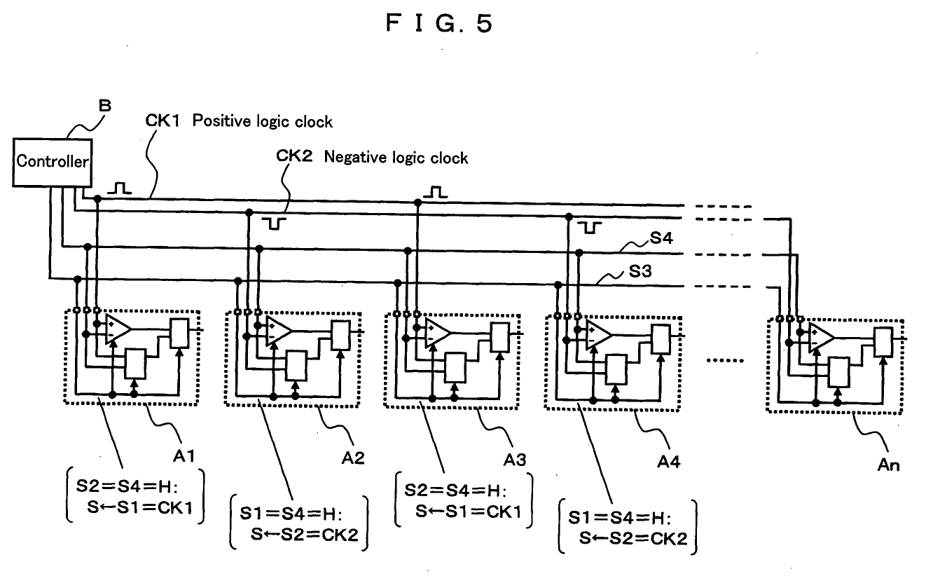

FIG. 5 is a circuit diagram for showing a structure of a display driver (data driver) according to a sixth embodiment of the present invention. This embodiment relates to a technique for reducing EMI.

In a display driver having a plurality of the signal transfer apparatuses A lined in parallel along the upper side of the liquid crystal display panel 11 as in FIG. 4, when a clock is transferred from the controller B via the signal wiring 12, the clock may become a cause of generating EMI (electromagnetic noise) against the data signal flowing in the neighboring signal wiring 12. This embodiment is designed to suppress such EMI.

As shown in FIG. 5, in the plurality of signal transfer apparatuses A arranged in parallel, the wiring connection state for odd-numbered signal transfer apparatuses A1, A3, - - - is different from the wiring connection state for the even-numbered signal transfer apparatuses A2, A4, - - - . The controller B provided in common for the plurality of signal transfer apparatuses A is constituted to output a positive logic clock CK1, a negative logic clock CK2, the selection signal S3, and a control signal S4. The signal transfer apparatuses A and the controller B are constituted with semiconductor integrated circuits.

In the odd-numbered signal transfer apparatuses A1, A3, - - - , the positive logic clock CK1 is inputted to a non-inverted input terminal (+) of the differential signal generating part 1, and the control signal S4 is inputted to an inverted input terminal (−). That is, the relations therebetween can be expressed as “the input signal S1 from the positive-electrode side input terminal I1=the positive logic clock CK1” and “the input signal S2 from the negative-electrode side input terminal I2=the control signal S4”. The odd-numbered signal transfer apparatuses A1, A3, - - - are under the specifications for the positive logic clock input mode.

On the other hand, for the odd-numbered signal transfer apparatuses A1, A3, - - - , the control signal S4 is inputted to the non-inverted input terminal (+) of the differential signal generating part 1, and the negative logic clock CK2 is inputted to the inverted input terminal (−). That is, the relations therebetween can be expressed as “the input signal S1 from the positive-electrode side input terminal I1=the control signal S4” and “the input signal S2 from the negative-electrode side input terminal I2=the negative logic clock CK2”. The even-numbered signal transfer apparatuses A2, A4, - - - are under the specifications for the negative logic clock input mode.

Regarding the selection signal S3, the odd-numbered signal transfer apparatuses A1, A3, - - - and the even-numbered signal transfer apparatuses A2, A4, - - - have the same relation.

Next, actions of the signal transfer apparatus according to the embodiment constituted in the above-described manner will be described.

In a state where the selection signal S3 is “H” level and the mode is set to the single-end signal receiving mode, the controller B outputs both the positive logic clock CK1 and the negative logic clock CK2.

In the odd-numbered signal transfer apparatuses A1, A3, - - - , the input signal S2 from the negative-electrode side input terminal I2, i.e. the control signal S4, is fixed to “H” level for the first selecting part E1. As a result, the input signal S1 from the positive-electrode side input terminal I1, i.e. the positive logic clock CK1, is selected.

On the other hand, for the even-numbered signal transfer apparatuses A2, A4, - - - , the input signal S1 from the positive-electrode side input terminal I1, i.e. the control signal S4, is fixed to “H” level for the first selecting part E1. As a result, the input signal S2 from the negative-electrode side input terminal I2, i.e. the negative logic clock CK2, is selected.

In this embodiment, the signal wiring of the positive logic clock CK1 and the signal wiring of the negative logic clock CK2 from the controller B to the signal transfer apparatus A are provided in parallel, and the signals traveling therethrough have opposite phases. Therefore, it is possible to offset the EMI generated from each wiring with that of the other, thereby enabling the EMI to be reduced. Further, this embodiment requires no special signal for switching between the positive logic input and the negative logic input.

Note here that the odd-numbered apparatuses may be the negative logic input mode and the even-numbered apparatuses may be the positive logic input mode.

What is claimed is:

1. A signal transfer apparatus, comprising:
a differential signal generating part which receives an input signal from a positive-electrode side input terminal and an input signal from a negative-electrode side input terminal, and outputs a differential signal obtained from said input signals from both the input terminals;
a first selecting part which receives a selection signal from a selection signal input terminal, said input signal from said positive-electrode side input terminal, and said input signal from said negative-electrode side input terminal, and selects and outputs either said input signal from said negative-electrode side input terminal or said input signal from said positive-electrode side input terminal in accordance with a logic of said selection signal and a logic of either said input signal from said positive-electrode side input terminal or said input signal from said negative-electrode side input terminal; and
a second selecting part which selects and outputs either an output of said differential signal generating part or an output of said first selecting part in accordance with said logic of said selection signal from said selection signal input terminal.

2. The signal transfer apparatus according to claim 1, wherein said differential signal generating part is controlled so that it is in an operational state when said selection signal is a first condition signal, and in a non-operational state when said selection signal is a second condition signal.

3. The signal transfer apparatus according to claim 1, wherein said first selecting part is controlled so that it is in an operational state when said selection signal is a second condition signal, and in a non-operational state when said selection signal is a first condition signal.

4. The signal transfer apparatus according to claim 1, wherein a delay adjusting part, which is capable of switching its delay effect in accordance with a logic of said selection signal, is inserted between said first selecting part and said second selecting part.

5. The signal transfer apparatus according to claim 1, wherein said first selecting part is formed to have its structural elements at the same level at both a positive electrode and a negative electrode, and a resistance value of wiring up to said positive-electrode side terminal and a resistance value of wiring up to said negative-electrode side input terminal are designed to be equal with each other.

6. The signal transfer apparatus according to claim 5, wherein said first selecting part is constituted with a NAND circuit and a NOR circuit.

7. The signal transfer apparatus according to claim 5, wherein said first selecting part is constituted only with a NOR circuit.

8. A display driver comprising a plurality of said signal transfer apparatuses as claimed in claim 1 arranged in parallel, wherein a first signal transfer apparatus that is in a mode for inputting a positive logic clock to said positive-electrode side input terminal and for inputting a logic-fixed control signal to said negative-electrode side input terminal, and a second signal transfer apparatus that is in a mode for inputting a negative logic clock to said negative-electrode side input terminal and for inputting said logic-fixed control signal to said positive-electrode side input terminal are arranged alternately.

9. A dot-matrix type display apparatus, comprising a data driver in which a plurality of signal transfer apparatuses as claimed in claim 1 are arranged in parallel; and a controller for supplying clocks and control signals to said plurality of signal transfer apparatuses.
